(19) United States
(12) Patent Application Publication
(10) Pub. No.: US 2014/0116496 A1
(43) Pub. Date: May 1, 2014

(54) MULTI-JUNCTION CPV PACKAGE AND METHOD

(71) Applicant: Ron HELFAN, Ramat Hasharon (IL)

(72) Inventor: Ron HELFAN, Ramat Hasharon (IL)

(21) Appl. No.: 13/665,948

(22) Filed: Nov. 1, 2012

(51) Int. Cl. H01L 31/052; H01L 31/18

(52) U.S. Cl. CPC H01L 31/0522; H01L 31/18
USPC 136/246; 438/65

(57) ABSTRACT

A multi junction CPV package device comprising: an anode carrier plate; a solar cell array adapted to be electrically connected with wire bonds to the anode carrier plate, the solar cell array comprising an active area; an SOE positionable on the solar cell array and the anode, the SOE forming a first aperture with a wall around at least a portion of the active area and a second aperture around at least a portion of the anode carrier plate, the wall of the first aperture comprising a UV-resistant material; and a cathode plate having an electrical insulation from the anode carrier plate and the cathode plate having a first surface having a thermal connection to the solar cell and a second surface opposed to the first surface, wherein the solar cell and the cathode plate have a thermal connection and the second surface is adapted to be surface-mounted to a PCB.

This application claims priority from U.S. Provisional Application No. 61/556,277, filed 6 Nov. 2011, whose disclosure is incorporated herein by reference.

### FIELD AND BACKGROUND OF THE INVENTION

Embodiments of the current invention relate to robust and reliable packaging for III-V semiconductors in general, and for packaging of Concentrated Photovoltaic (CPV) multi-junction cells and methods thereof, in particular.

Solar energy generation has been a subject of increasing interest in recent decades, as a major contributor in the field of sustainable energy of development. One aspect of solar energy generation has been in the field of photovoltaics, namely direct generation of electricity from solar radiation. Concentrated Photovoltaics (CPV) have recently drawn interest, as they hold the promise of substantially increased energy conversion efficiencies, as compared to conventional silicon-based solar cells.

Kurtz, in a publication entitled: “CPV 101: Intro to CPV Technology: Opportunities and Challenges”, NREL/PR-520-46924, 26 Oct. 2009, which is incorporated by reference discusses a number of developments related to CPV. Reference is presently made to FIG. 1, prior art—from Kurtz, which is a timeline graph showing the development of solar cells over time versus their respective energy conversion efficiencies. It can be clearly seen that from the 1990's through today, multijunction CPV cells appear to have the highest energy efficiencies compared to alternate technologies.

In order for CPV cells to be more widely disseminated and to take advantage of the increased efficiencies demonstrated for these cells and apply them to commercially-feasible projects, there is a need for robust, cost effective, multi junction CPV packaging and manufacturing.

Shook et al., in U.S. patent application Ser. No. 12/250,034, whose disclosure is incorporated herein by reference, describes a lead frame receiver package comprising a first conductive element, a solar cell electrically coupled to the first conductive element and comprising an active area, and a mold compound disposed on the lead frame and the solar cell. The mold compound defines a first aperture wall over at least a portion of the active area and a second aperture wall over at least a portion of the first conductive element. The mold compound includes a reflective surface to improve heat resistance around an aperture wall receiving solar radiation.

In U.S. Pat. No. 7,977,777, whose disclosure is incorporated herein by reference, Frederici et al. describes a lead frame thermoplastic package for a solar cell. The lead frame is either a single-lead frame design or a dual-lead frame design. The single-lead frame design is made up of a single-lead metal frame. The dual-lead frame design is made up of a die pad lead frame, a wire bond lead frame, and being encapsulated in a thermoplastic resin. Optionally, the lead frame is incorporated into a solar cell including the lead frame, a semiconductor die, a diode, an optics system, and an integrated electrical connection system.

The prior art does not identify packages as standard SMT components. As a result, additional wiring/connection is required to interconnect each of the packaged cells. Additionally, UV protection of the non-metallic segments described in the prior art is afforded by the application of reflective polymeric coatings by using a conventional inherently-reflective polymer—which are exposed directly to UV radiation, known to attack conventional polymeric materials. Alternative prior art methods may include additional processes to apply reflective coatings. Additionally, polymers at high temperatures and under intense sunlight (including the UV spectrum) can degrade, delaminate, degas, and/or transform which leads to reliability and performance concerns.

There is therefore a need for cost effective, multi-junction CPV and economic solutions for CPV packages having high performance and long lifetimes.

### SUMMARY OF THE INVENTION

According to the teachings of the present invention there is provided a multi junction CPV package device comprising: an anode carrier plate; a solar cell array adapted to be electrically connected with wire bonds to the anode carrier plate, the solar cell array comprising an active area; an SOE positionable on the solar cell array and the anode, the SOE forming a first aperture with a wall around at least a portion of the active area and a second aperture around at least a portion of the anode carrier plate, the wall of the first aperture comprising a UV-resistant material; and a cathode plate having an electrical insulation from the anode carrier plate and the cathode plate having a first surface having a thermal connection to the solar cell and a second surface opposed to the first surface, wherein the solar cell and the cathode plate have a thermal connection and the second surface is adapted to be surface-mounted to a PCB. Preferably the solar cell array is a CPV cell type chosen from at least one in the list including: silicon-based; single junction; dual-junction; multi-junction; and III-V-based. Most preferably, the second surface of the cathode has a plurality of bonding pads disposed thereupon, the bonding pads adapted to be bonded to a circuit board using SMT and reflow processes, affording the multi junction CPV package device a mechanical, thermal, and electrical bond to the circuit board. Typically, the circuit board is adapted to serve as a heat sink. Most typically, the anode carrier plate is further adapted to serve as a lens holder for a secondary optical element.

Preferably, the package device further comprises an optical encapsulation cavity positionable above the solar cell and beneath the SOE. Most preferably, the the package device further comprises an insulated housing adapted to protect the solar cell from the environment. Typically, the anode carrier plate, the solar cell array, the SOE, and the cathode plate have substantially equal coefficients of thermal expansion. Most typically, the thermal connection is fabricatable from at least one UV-resistant and dielectric material chosen from the list including: silicone; ceramic; glass; Kapton®; silica; silicon; and glass-fiber. Preferably, the package device further comprises a lead frame. Most preferably, the package device further comprises a dual lead frame.

According to the teachings of the present invention there is further provided a method of fabricating a multi junction CPV package device comprising the steps of: taking an anode carrier plate; connecting a solar cell array electrically connected to the anode carrier plate using wire bonds, the solar cell array comprising an active area; positioning a SOE on the solar cell array and the anode, the SOE forming a first aperture with a wall around at least a portion of the active area and a second aperture around at least a portion of the anode carrier plate, the wall of the first aperture comprising a UV-resistant material; and configuring a cathode plate electrically insulated from the anode carrier plate and having a first surface thermally connected to the solar cell and a second surface opposed to the first surface, wherein the second surface is surface-mounted to a PCB. Preferably, the solar cell array is a III-V multi junction cell chosen from at least one in the list including: CPV and HCPV. Most preferably, a plurality of bonding pads are disposed on the second surface of the cathode. Typically, the thermal connection is fabricated from at least one UV-resistant and dielectric material chosen from the list including: silicone; ceramic; glass; Kapton®; silica; silicon; and glass-fiber.

### BRIEF DESCRIPTION OF THE DRAWINGS AND APPENDICES

The invention is herein described, by way of example only, with reference to the accompanying drawings, wherein:

FIG. 1 is a prior art timeline graph showing the development of solar cells over time versus their respective energy conversion efficiencies; and

FIGS. 2-4 are are schematic, sectional, and exploded pictorial representations, respectively, of a multi-junction CPV package, in accordance with embodiments of the current invention.

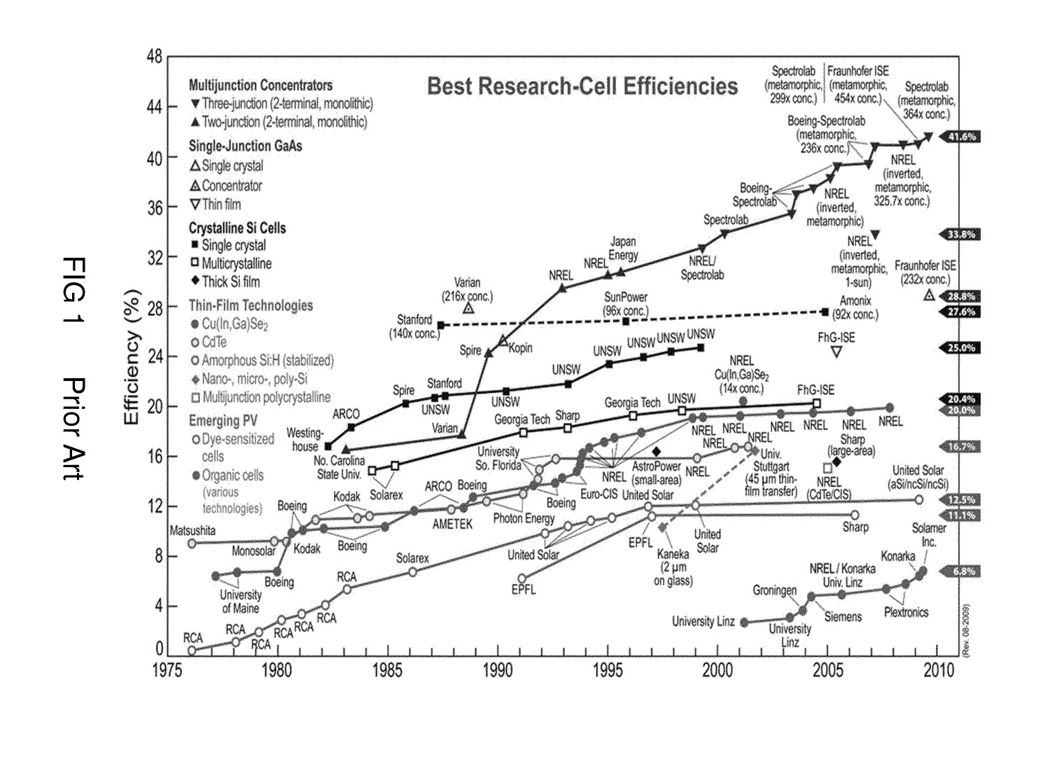

### DETAILED DESCRIPTION OF THE PREFERRED EMBODIMENTS

Embodiments of the current invention are related to robust and reliable packaging for III-V semiconductors in general, and for packaging of Concentrated Photovoltaic (CPV) multi-junction cells and methods thereof, in particular.

In the specification and claims which follow, the term “solar cell” or abbreviated as “cell” both refer to a “multi junction cell” of a CPV package—as further described hereinbelow.

Embodiments of the current invention relate to robust and reliable packaging for III-V semiconductors, in general, and for CPV multi junction cells having the following constraints:
1. Operation in high temperatures ranging from 60 to 500 degrees C., and even to 1000 degrees C. in very high concentration ratios and under misalignment for example (at the concentrated foci and hot spots of the optical system);
2. Operation in concentrated sunlight in the range of substantially 200 nm to 1800 nm wavelengths, therefore being substantially UV-resistant;
3. Operation for periods of up to 25 years without significant degradation in power production and without significant reliability issues as specified in IEC62108;
4. Typical semiconductor packaging utilizes plastics and thermoplastics; however these materials are sensitive to high temperatures and UV radiation. For example, degradation is expected when these materials are exposed to UV. Additionally, when a CPV cell package is exposed to high solar radiation concentration ratios of X500 to X1000 and higher, thermal “hot spots” may be expected to develop and therefore thermoplastic materials may not survive for long periods. Although sensitive polymeric materials and components can be shielded as described in the prior art, such shielding can lead to additional costs of parts and manufacturing processes, in addition to reliability concerns related to coatings under intense sunlight yielding delamination and other degradations. Embodiments of the current invention therefore utilize alternate UV resistance as described hereinbelow.

An optimal CPV cell package should have the following operational capabilities and material qualities:
1. Endurance and survival of high temperature with no significant operational degradation over time.
2. Optimal matching of thermal expansion coefficients of the various components and materials of the package. This point is of dual concern because it is related to both power generation and optical considerations. Misalignment of components due, for example, to mechanical stresses caused by different thermal expansion coefficients between materials can lead to hot spots and to higher UV radiation intensities on areas other than the cell and this impact both performance and reliability.
3. Endurance and survival of concentrated sunlight throughout a typical operational spectrum, including no significant UV-related degradation over time.
4. Have excellent heat dissipation for the cell—to maintain lower operating temperatures to optimize performance and increase reliability. One way to dissipate such heat is to thermally connect the cell to a heat sink substrate such as a PCB.
5. Have excellent electrical conductivity—to allow optimal power extraction from the cell.
6. Have straightforward integration of glass optical elements without large differences in thermal expansion coefficients to minimize mechanical stresses in operation. For example, example glass-to-glass interfaces or glass-to-metal and glass-silica interfaces having similar thermal coefficients of expansion are considered optimal.
7. Have conventional wire and wedge bonding of aluminum and gold wires from the cell bus bars to the package bus bars, as well as mesh bonding, etc.; however this point is not critical since of the bonding method may change with changes in technology.
8. Have soldering of the cells, vacuum, eutectic, and other connection methods as known in the art, in addition to the use of thermal adhesives substantially free of voids.
9. Packaging suitable for coating processes of metals. For example, packaging typically used in PCB production.
10. Allow integration of diodes and boosters in a buried fashion—to afford thermal and UV protection.
11. Have electrical insulation between the cathode and anode of the cell and additionally at the package level.
12. Allow for standard and common tape and reel configuration as well as tray configuration to meet with wide array of SMT practices and manufacturing assembly equipment capabilities.

The list of constraints and operational capabilities noted hereinabove dictates an optimal choice of materials such as:
a. Ceramics—such as, but not limited to alumina—for insulators or dielectrics
b. Glass—for insulators or dielectrics
c. Copper—for electrical and thermal conductivity
   d. Silicones—to serve as adhesives offering excellent UV resistance, unlike epoxy-based materials

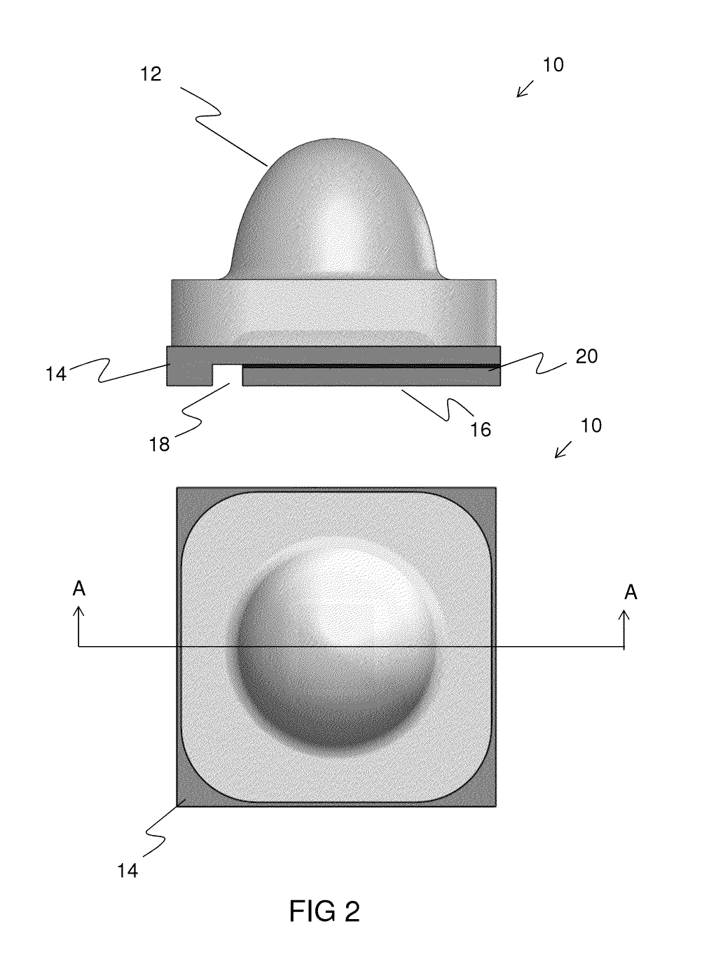

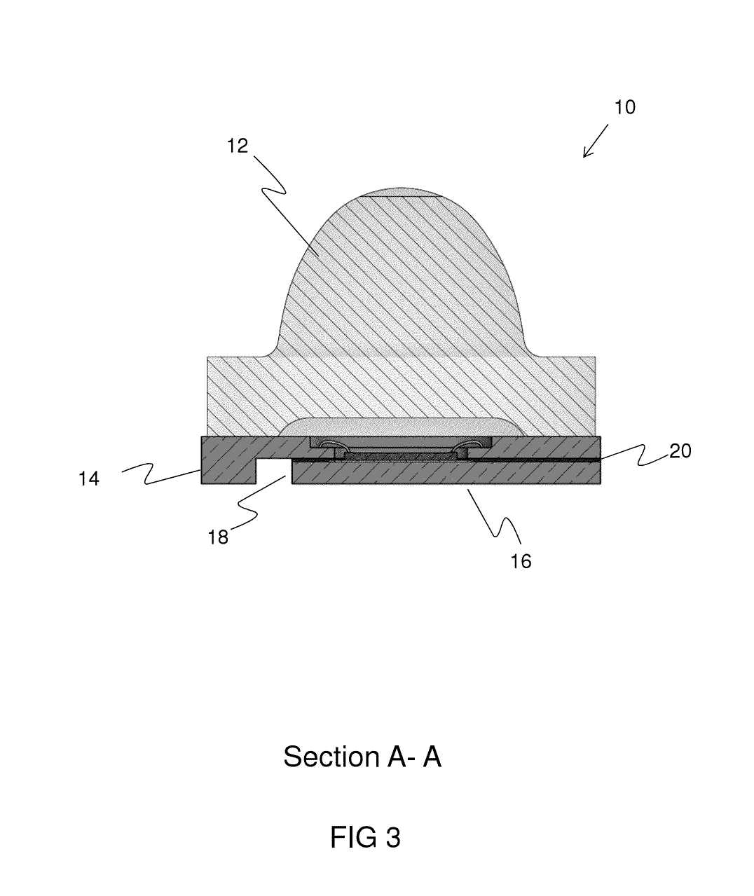

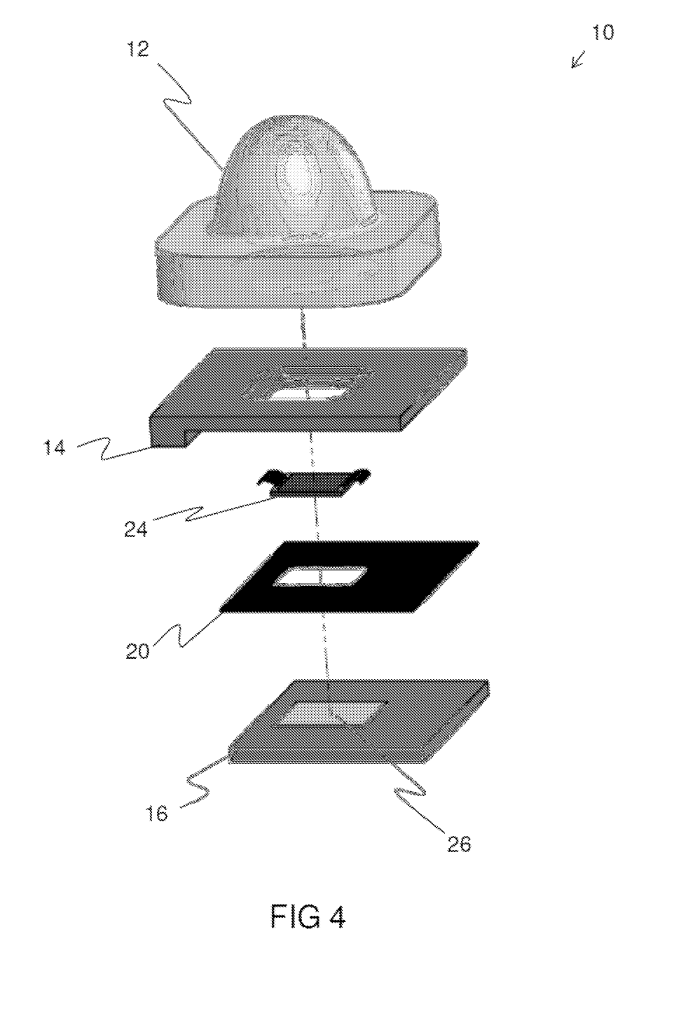

Reference is currently made to FIGS. 2-4, which are schematic, sectional, and exploded pictorial representations, respectively, of a multi junction CPV package 10, in accordance with embodiments of the current invention.

Multi junction CPV package 10 comprises a secondary optical element (SOE) 12, an anode carrier plate 14, a cathode plate 16, a dielectric cavity 18, and a dielectric heat transfer layer 20. Additionally, the multi junction CPV package further includes a multi-junction cell 24 and a solder surface 26 to which the multi junction cell is adhered, as described further hereinbelow.

SOE 12 is similar in function to typical second stage optical elements used in concentrated photovoltaics, as known in the art. Anode carrier plate 14 is a typically formed of copper, which allows for straightforward wire bonding of the leads of multi-junction cell 24 to the anode carrier plate. The typical copper material of cathode plate 16, allows for straightforward soldering of multi-junction cell 24 onto cathode plate 16, enhancing heat transfer between the cell and the plate and forming a good electrical contact between the two.

Dielectric cavity 18 may be a void or alternatively, it may be filled with any suitable dielectric material to insulate between anode carrier plate 14 and cathode plate 16. The structure of dielectric cavity 18 allows the bottom surface of multi-junction CPV package 10 to have a plurality of bonding pads (not shown in the figures) attached for SMT (surface mounting technology) and/or reflow soldering and assembly, as known in the art—serving to enhance heat transfer and electrical conductivity and provide assembly cost-effectiveness.

In embodiments of the current invention, multi-junction CPV package 10 may be assembled directly on a PCB (printed circuit board) using SMT—as opposed to prior art packages, which typically require additional wiring and/or additional assembly steps.

Dielectric heat transfer layer 20 is a thermally conductive and electrically insulated dielectric layer between anode carrier plate 14, a cathode plate 16. The dielectric heat transfer layer is typically formed from epoxy, Kapton®, silicon, silica, glass, or glass fiber materials.

Embodiments of the current invention include incorporation of UV resistant polymers and other UV resistant materials including such as silicon or alternatively ceramic or glass as an insulator\molding agent materials. Where UV-sensitive materials are used (such as in the multi junction cell itself) the materials are not exposed to direct sunlight but are instead covered by a metallic layer.

Other embodiments of the current invention include fabrication of Multi-junction CPV package 10 using well-known lead frame, dual lead frame Techniques—as opposed to tape-and-reel techniques—to allow cheaper component costs and mass production.

An embodiment or the present invention includes a method of fabricating Multi junction CPV package 10, including the following steps:
1. taking an anode carrier plate;
2. connecting a solar cell array electrically connected to the anode carrier plate using wire bonds, where the solar cell array comprises an active area;
3. positioning a SOE on the solar cell array and the anode, where the SOE forms a first aperture with a wall around at least a portion of the active area and a second aperture around at least a portion of the anode carrier plate, the wall of the first aperture comprising a UV-resistant material; and
4. configuring a cathode plate electrically insulated from the anode carrier plate and having a first surface thermally connected to the solar cell and a second surface opposed to the first surface.

The second surface in the method steps listed hereinabove is surface-mounted to a PCB.

It will be appreciated that the above descriptions are intended only to serve as examples, and that many other embodiments are possible within the scope of the present invention as defined in the appended claims.

1. A concentrated photovoltaic (CPV) package device having a bottom surface, comprising:
an anode carrier plate comprising part of the bottom surface;
a solar cell electrically connected with wire bonds to the anode carrier plate, the solar cell comprising an active area;
a secondary optical element (SOE) positionable on the solar cell and the anode, the SOE configured as a first aperture with a wall around at least a portion of the active area and a second aperture around at least a portion of the anode carrier plate, the wall of the first aperture comprising at least one UV-resistant and dielectric material chosen from the list including: silicone; ceramic; glass; silica; silicon; and glass-fiber,
a cathode plate having an electrical insulation from the anode carrier plate and the cathode plate having a first surface having a thermal and an electrical connection to the solar cell and a second surface opposed to the first surface, the second surface comprising part of the bottom surface; and
a plurality of bonding pads configured on the bottom surface, the bonding pads surface-mountable directly to a printed circuit board (PCB) by means of surface mounting technology (SMT).

2. The package device of claim 1, wherein the solar cell is a CPV cell type chosen from at least one in the list including:
silicon-based; single junction; dual-junction; multi-junction; and III-V-based.

3. The package device of claim 1, wherein the bonding pads are surface-mountable directly to the PCB by means of reflow soldering, and the package device has a mechanical, thermal, and electrical bond to the PCB.

4. The package device of claim 3, wherein the PCB is configured as a heat sink.

5. The package device of claim 1, wherein the anode carrier plate is further configured as a lens holder for the SOE.

6. The package device of claim 1, further comprising an optical encapsulation cavity positionable above the solar cell and beneath the SOE.

7. The package device of claim 1, further comprising an insulated housing adapted to protect the solar cell from the environment.

8. The package device of claim 1, wherein the anode carrier plate, the solar cell array, the SOE, and the cathode plate have substantially equal coefficients of thermal expansion.

9. (canceled)

10. A method of fabricating a concentrated photovoltaic (CPV) package device, having a bottom surface, comprising the steps of:
taking an anode carrier plate, the carrier plate forming part of the bottom surface;
connecting a solar cell electrically to the anode carrier plate using wire bonds, the solar cell comprising an active area;
positioning a secondary optical element (SOE) on the solar cell and the anode, the SOE forming a first aperture with a wall around at least a portion of the active area and a second aperture around at least a portion of the anode carrier plate, the wall of the first aperture comprising a UV-resistant material;
configuring a cathode plate electrically insulated from the anode carrier plate and having a first surface thermally and electrically connected to the solar cell and a second surface opposed to the first surface, the second surface forming part of the bottom surface; and
surface-mounting the bottom surface to a printed circuit board (PCB).

11. The method of claim 10, whereby the solar cell is a CPV cell type chosen from at least one in the list including: silicon-based; single junction; dual-junction; multi-junction; and III-V-based.

12-13. (canceled)
